(19) United States
(12) Patent Application Publication
(10) Pub. No.: US 2011/0037507 A1
(43) Pub. Date: Feb. 17, 2011

(54) MIXER WITH DIFFERENTIAL DC OFFSET CANCELLATION FUNCTION

(75) Inventors: Hyeon Seok HWANG, Seoul (KR); Yoo Sam Na, Seoul (KR); Byeong Hak Jo, Suwon (KR)

Correspondence Address: LOWE HAUPTMAN HAM & BERNER, LLP, 1700 DIAGONAL ROAD, SUITE 300, ALEXANDRIA, VA, 22314, US

(73) Assignee: SAMSUNG ELECTRO-MECHANICS CO., LTD., Suwon (KR)

(21) Appl. No.: 12/640,173

(22) Filed: Dec. 17, 2009

(30) Foreign Application Priority Data
Aug. 12, 2009 (KR) 10-2009-0074270

(51) Int. Cl. H03L 5/00

(52) U.S. Cl. 327/307

(57) ABSTRACT

A mixer with a differential DC offset cancellation function includes: a load unit including a first load unit and a second load unit; a mixing unit biased by current transferred from the load unit to mix inputs signal and oscillation signals; a first output voltage detection unit detecting an output voltage of the first output terminal; a second output voltage detection unit detecting an output voltage of the second output terminal; a first injection/extraction circuit unit injecting current into the first load unit or extracting current from the first load unit according to the size of a first detection voltage; a second injection/extraction circuit unit injecting current into the second load unit or extracting current from the second load unit according to the size of a second detection voltage; and a current regulation unit regulating an overall current flowing across the first and second injection/extraction circuit units.

### CROSS-REFERENCE TO RELATED APPLICATIONS

This application claims the priority of Korean Patent Application No. 10-2009-0074270 filed on Aug. 12, 2009, in the Korean Intellectual Property Office, the disclosure of which is incorporated herein by reference.

### BACKGROUND OF THE INVENTION

1. Field of the Invention

The present invention relates to a mixer with a differential DC offset cancellation function applicable to a reception system and, more particularly, to a mixer with a differential DC offset cancellation function capable of injecting and extracting a load current according to an output voltage to thereby compensate for a differential DC offset and thus improve linearity.

2. Description of the Related Art

In general, a mixer performs signal frequency conversion such that it switches an input signal according to an oscillation signal to up-convert or down-convert the input signal. In some cases, the mixer is implemented to have a differential structure providing a differential output with respect to a differential input, and in this case, if a DC offset exists in the mixer with the differential structure, the mixer cannot properly convert signal conversion, so the DC offset should be canceled.

In general, the method of canceling a DC offset includes two methods: a first method is uniformly maintaining a common mode DC of an output; and a second method is compensating for a mismatch of a differential mode DC offset of an output.

As for the second method, the mismatch of the differential mode DC offset of an output occurs during a process, a layout, or a connection to an application circuit, which cannot be accurately predicted through simulation and cannot be accurately compensated for.

Thus, in order to remove such shortcomings, a digital control circuit is additionally installed or a compensation circuit is configured. However, such additional circuits degrade required gain characteristics, linearity, and noise characteristics.

In addition, in order to compensate for the current due to mismatch, a DC offset canceling mixer is used.

First, in the method for compensating for the current due to the mismatch, current is generated at the level of voltage difference between detected voltages, and is then fed back to the mixer circuit to perform compensation. In this case, a compensation current value is determined by a current value of a current source connected with a ground.

Accordingly, in this method, if the current exceeds the level of the compensation current, it cannot be compensated for. Also, if too excessive a current is used, a load resistance is reduced to make it impossible to obtain a large gain overall.

In addition, the method of using the DC offset canceling mixer is controlling a load resistance. That is, in this method, one side of a load resistance is configured to be controlled, whereby an error of an output level is checked and a resistance value is manually adjusted to cancel a DC offset. In this method, a compensation degree of the error value is determined depending on how finely the resistance value can be adjusted.

In this respect, however, if a plurality of resistors are employed to adjust the resistance value too finely, a parasitic capacitance component would increase to degrade the linearity.

### SUMMARY OF THE INVENTION

An aspect of the present invention provides a mixer with a differential DC offset cancellation function capable of injecting and extracting a load current according to an output voltage to thereby compensate for a differential DC offset and thus improve linearity.

According to an aspect of the present invention, there is provided a mixer with a differential DC offset cancellation function, including: a load unit including a first load unit connected between a power source voltage terminal and a first output terminal and a second load unit connected between the power source voltage terminal and a second output terminal; a mixing unit biased by current transferred from the load unit to mix input signals and oscillation signals and outputting the mixed signal generated through the mixing operation through the first and second output terminals; a first output voltage detection unit detecting an output voltage of the first output terminal; a second output voltage detection unit detecting an output voltage of the second output terminal; a first injection/extraction circuit unit injecting current into the first load unit or extracting current from the first load unit according to the size of a first detection voltage detected by the first output voltage detection unit; a second injection/extraction circuit unit injecting current into the second load unit or extracting current from the second load unit according to the size of a second detection voltage detected by the second output voltage detection unit; and a current regulation unit regulating an overall current flowing across the first and second injection/extraction circuit units.

According to another aspect of the present invention, there is provided a mixer with a differential DC offset cancellation function, including: a load unit including a first load unit connected between a power source voltage terminal and a first output terminal and a second load unit connected between the power source voltage terminal and a second output terminal; a mixing unit having a Gilbert cell structure connected between the load unit and a ground, mixing input signals and oscillation signals, and outputting the signal generated through the mixing operation through the first and second output terminals; a first output voltage detection unit detecting an output voltage of the first output terminal; a second output voltage detection unit detecting an output voltage of the second output terminal; a first injection/extraction circuit unit injecting current into the first load unit or extracting current from the first load unit according to the size of a first detection voltage detected by the first output voltage detection unit; a second injection/extraction circuit unit injecting current into the second load unit or extracting current from the second load unit according to the size of a second detection voltage detected by the second output voltage detection unit; and a current regulation unit regulating an overall current flowing across the first and second injection/extraction circuit units.

The mixing unit may include: a gain stage including first and second MOS transistors receiving an input signal; and a switching stage including third and fourth MOS transistors switching an input signal transferred from the first MOS transistor of the gain stage according to an oscillation signal and fifth and sixth transistors switching an input signal transferred from the second MOS transistor of the gain stage according to an oscillation signal.

The first load unit may include first and second resistors connected in series between the power source voltage terminal and the first output terminal, and the second load unit may include third and fourth resistors connected in series between the power source voltage terminal and the second output terminal.

The first output voltage detection unit may include an input terminal connected to a first connection node between the first and second resistors of the first load unit, and the second output voltage detection unit may include an input terminal connected to a second connection node between the third and fourth resistors of the second load unit.

The first injection/extraction circuit unit may include: a first PMOS transistor having a source connected with the power source voltage terminal, a gate connected with an output terminal of the first output voltage detection unit, and a drain connected to the first connection node between the first and second resistors of the first load unit; and a second NMOS transistor having a drain connected to the first connection node between the first and second resistors of the first load unit, a gate connected to the output terminal of the first output voltage detection unit, and a source connected to the current regulation unit.

The second injection/extraction circuit unit may include: a third PMOS transistor having a source connected to the power source voltage terminal, a gate connected to an output terminal of the second output voltage detection unit, and a drain connected to the second connection node between the third and fourth resistors of the second load unit; and a fourth NMOS transistor having a drain connected to the second connection node between the third and fourth resistors of the second load unit, a gate connected to the output terminal of the second output voltage detection unit, and a source connected to the current regulation unit.

The current regulation unit may include: a fifth NMOS transistor having a drain connected to a connection node between the source of the second MOS transistor and that of the fourth transistor, a gate connected to a bias voltage, and a source connected to a ground.

In the first injection/extraction circuit unit, the first and second transistors may operate complementarily according to the size of the first detection voltage from the first output voltage detection unit.

When the first transistor is turned on, the first injection/extraction circuit unit may inject current to the first load unit through the first transistor, and when the second transistor is turned on, the first injection/extraction circuit unit may extract current from the first load unit through the second transistor.

In the second injection/extraction circuit unit, the third and fourth transistors may operate complementarily according to the size of the second detection voltage from the second output voltage detection unit.

When the third transistor is turned on, the second injection/extraction circuit unit may inject current to the second load unit through the third transistor, and when the fourth transistor is turned on, the second injection/extraction circuit unit may extract current from the second load unit through the fourth transistor.

The first transistor of the first injection/extraction circuit unit may complementarily operate with the third transistor of the second injection/extraction circuit unit.

The second transistor of the first injection/extraction circuit unit may complementarily operate with the fourth transistor of the second injection/extraction circuit unit.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a circuit diagram of a mixer having a differential DC offset cancellation function according to an exemplary embodiment of the present invention;

FIG. 2 illustrates an example of implementation of a first output voltage detection unit according to an exemplary embodiment of the present invention;

FIG. 3 is a conceptual view showing voltage compensation of a first injection/extraction circuit unit according to an exemplary embodiment of the present invention;

FIG. 4 is graphs showing a desired signal and tertiary harmonics according to an exemplary embodiment of the present invention; and

FIG. 5 is graphs showing a desired signal and secondary harmonics according to an exemplary embodiment of the present invention.

### DETAILED DESCRIPTION OF THE PREFERRED EMBODIMENT

Exemplary embodiments of the present invention will now be described in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art. In the drawings, the shapes and dimensions may be exaggerated for clarity, and the same reference numerals will be used throughout to designate the same or like components.

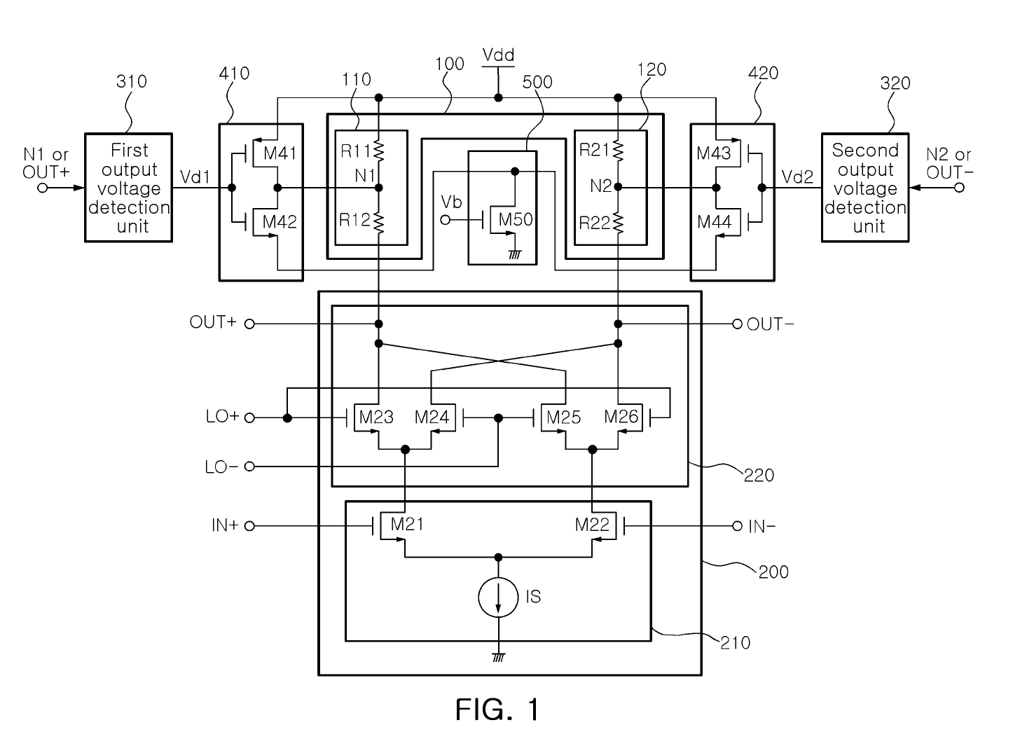

FIG. 1 is a circuit diagram of a mixer having a differential DC offset cancellation function according to an exemplary embodiment of the present invention. With reference to FIG. 1, the mixer with a differential DC offset cancellation function includes a load unit 100 including a first load unit 110 connected between a power source voltage terminal Vdd and a first output terminal OUT+ and a second load unit 120 connected between the power source voltage terminal Vdd and a second output terminal OUT−; a mixing unit 200 biased by current transferred from the load unit 100 to mix input signals IN+ and IN− and oscillation signals LO+ and LO−, and outputting the mixed signal generated through the mixing operation through the first and second output terminals OUT+ and OUT−; a first output voltage detection unit 310 detecting an output voltage of the first output terminal OUT+; a second output voltage detection unit 320 detecting an output voltage of the second output terminal OUT−; a first injection/extraction circuit unit 410 injecting current into the first load unit 110 or extracting current from the first load unit 110 according to the size of a first detection voltage Vd1 detected by the first output voltage detection unit 310; a second injection/extraction circuit unit 420 injecting current into the second load unit 120 or extracting current from the second load unit 120 according to the size of a second detection voltage Vd2 detected by the second output voltage detection unit 320; and a current regulation unit 500 regulating an overall current flowing across the first and second injection/extraction circuit units 410 and 420.

The first load unit 110 may include first and second resistors R11 and R12 connected in series between the power source voltage terminal Vdd and the first output terminal OUT+, and the second load unit 120 may include third and fourth resistors R11 and R12 connected in series between the power source voltage terminal Vdd and the second output terminal OUT−.

The mixing unit 200 may have a Gilbert cell structure in which the mixing unit 200 is connected between the load unit 100 and a ground. In this case, the mixing unit 200 may include a gain stage 210 that amplifies input signals transferred from the first and second input terminals IN+ and IN− and a switching stage 220 that switches an input signal transferred from the gain stage 210 according to an oscillation signal through first and second oscillation terminals LO+ and LO−, and outputs the same through the first and second output terminals OUT+ and OUT−.

The gain stage 210 includes a first MOS transistor M21 having a gate connected to the first input terminal IN+, a drain connected to the switching stage 220, and a source, a second MOS transistor M22 having a gate connected to the second input terminal IN−, a drain connected to the switching stage 220, and a source connected with the source of the first MOS transistor M21, and a current source is connected between a connection node between the source of the first MOS transistor M21 and the source of the second MOS transistor M22 and a ground.

The switching stage 220 includes a third MOS transistor M23 having a drain connected to the first load unit 110, a gate connected to the first oscillation terminal LO+, and a source connected to the drain of the first MOS transistor M21, a fourth MOS transistor M24 having a drain connected to the second load unit 120, a gate connected to the second oscillation terminal LO−, and a source connected to the drain of the first MOS transistor M21, a fifth MOS transistor M25 having a drain connected to the first load unit 110, a gate connected to the second oscillation terminal LO−, and a source connected to the drain of the second MOS transistor M22, and a sixth MOS transistor M26 having a drain connected to the second load unit 120, a gate connected to the first oscillation terminal LO+, and a source connected to the drain of the second MOS transistor M22.

The first output voltage detection unit 310, a detection node, may be connected to a first connection node N1 between the first and second resistors R11 and R12 or may be connected to the first output terminal OUT+.

Likewise, the second output voltage detection unit 320, a detection node, may be connected to a second connection node N2 between the third and fourth resistors R21 and R22 or may be connected to the second output terminal OUT−.

With reference to FIG. 1, the first output voltage detection unit 310 may include an input terminal connected to the first connection node N1 between the first and second resistors R11 and R12, and the second output voltage detection unit 320 may have an input terminal connected with the second connection node N2 between the third and fourth resistors R21 and R22.

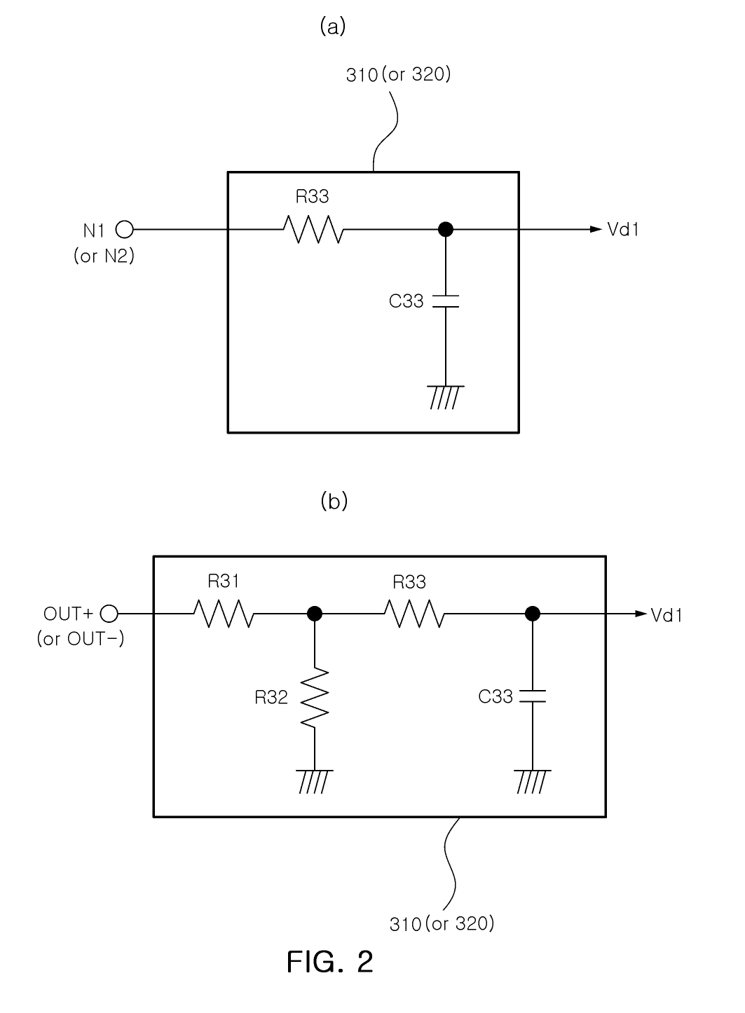

FIG. 2(a) and FIG. 2(b) show implementation of the first output voltage detection unit 310 (or the second output voltage detection unit 320). With reference to FIG. 2(a), when the first output voltage detection unit 310 (or the second output voltage detection unit 320) is connected to the first connection node N1 (or to the second connection node N2), it may include a resistor R33 and a capacitor C33.

Differently, with reference to FIG. 2(b), when the first output voltage detection unit 310 (or the second output voltage detection unit 320) is connected to the first output terminal OUT+(or the second output terminal OUT−), it may include first and second distribution resistors R31 and R32, the resistor R33 that outputs voltage distributed by the first and second distribution resistors R31 and R32, and the capacitor C33.

With reference to FIG. 1, the first injection/extraction circuit unit 410 may include a first PMOS transistor M41 having a source connected to the power source voltage terminal Vdd, a gate connected with an output terminal of the first output voltage detection unit 310, and a drain connected to the first connection node N1 between the first and second resistors R11 and R12 of the first load unit 110; and a second NMOS transistor M42 having a drain connected to the first connection node N1 between the first and second resistors R11 and R12 of the first load unit 110, a gate connected to the output terminal of the first output voltage detection unit 310, and a source connected to the current regulation unit 500.

The second injection/extraction circuit 420 unit may include: a third PMOS transistor M43 having a source connected to the power source voltage terminal Vdd, a gate connected to an output terminal of the second output voltage detection unit 320, and a drain connected to the second connection node N2 between the third and fourth resistors R21 and R22 of the second load unit 120; and a fourth NMOS transistor M44 having a drain connected to the second connection node N2 between the third and fourth resistors R21 and R22 of the second load unit 120, a gate connected to the output terminal of the second output voltage detection unit 320, and a source connected to the current regulation unit 500.

The current regulation unit 500 may include: a fifth NMOS transistor M50 having a drain connected to a connection node between the source of the second MOS transistor M42 and the source of the fourth transistor M44, a gate connected to a bias voltage Vb, and a source connected to a ground.

In the first injection/extraction circuit unit 410, the first and second transistors M41 and M42 operate complementarily according to the size of the first detection voltage Vd1 transferred from the first output voltage detection unit 310.

Namely, when the first transistor M41 is turned on and the second transistor M42 is turned off, current is injected into the first load unit 110 through the first transistor M41, and when the first transistor M41 is turned off and the second transistor M42 is turned on, current is extracted from the first load unit 110 through the second transistor M42.

In the second injection/extraction circuit unit 420, the third and fourth transistors M43 and M44 operate complementarily according to the size of the second detection voltage Vd2 from the second output voltage detection unit 320.

Namely, when the third transistor M43 is turned on and the fourth transistor M44 is turned off, current is injected into the second load unit 120 through the third transistor M43, and when the third transistor M43 is turned off and the fourth transistor M44 is turned on, current is extracted from the second load unit 120 through the fourth transistor M44.

Accordingly, the first transistor M41 of the first injection/extraction circuit unit 410 may operate complementarily with the third transistor M43 of the second injection/extraction circuit unit 420, and the second transistor M42 of the first injection/extraction circuit unit 410 may operate complementarily with the fourth transistor M44 of the second injection/extraction circuit unit 420.

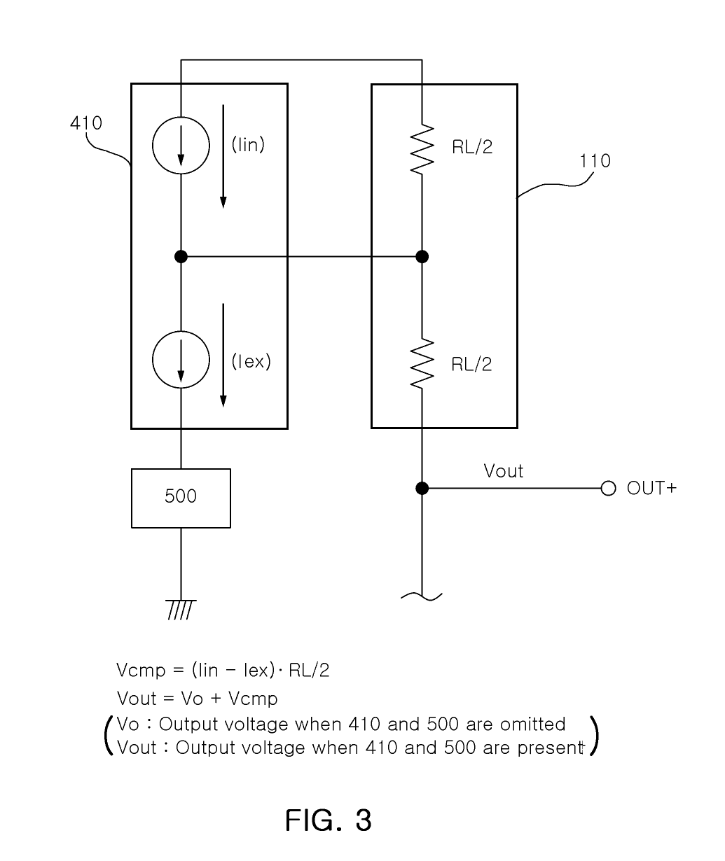

FIG. 3 is a conceptual view showing voltage compensation of the first injection/extraction circuit unit 410 according to an exemplary embodiment of the present invention. With reference to FIG. 3, in the first injection/extraction circuit unit 410, when the first transistor M41 is turned on, the second transistor M42 is turned off, so current Iin flowing across the first transistor M41 is injected into the load unit 110.

Meanwhile, when the first transistor M41 is turned off and the second transistor M42 is turned on, a portion (Iex) of the current flowing across the load unit 110 through the second transistor M42 is extracted. According to this operation, a compensation voltage Vcmp compensated for by the first injection/extraction circuit unit 410 is determined by Equation 1 shown below:

Vcmp=(Iin−Iex)*RL/2 [Equation 1]

The concept of a voltage compensation of the second injection/extraction circuit unit 420 is the same as that of the voltage compensation of the first injection/extraction circuit unit 410.

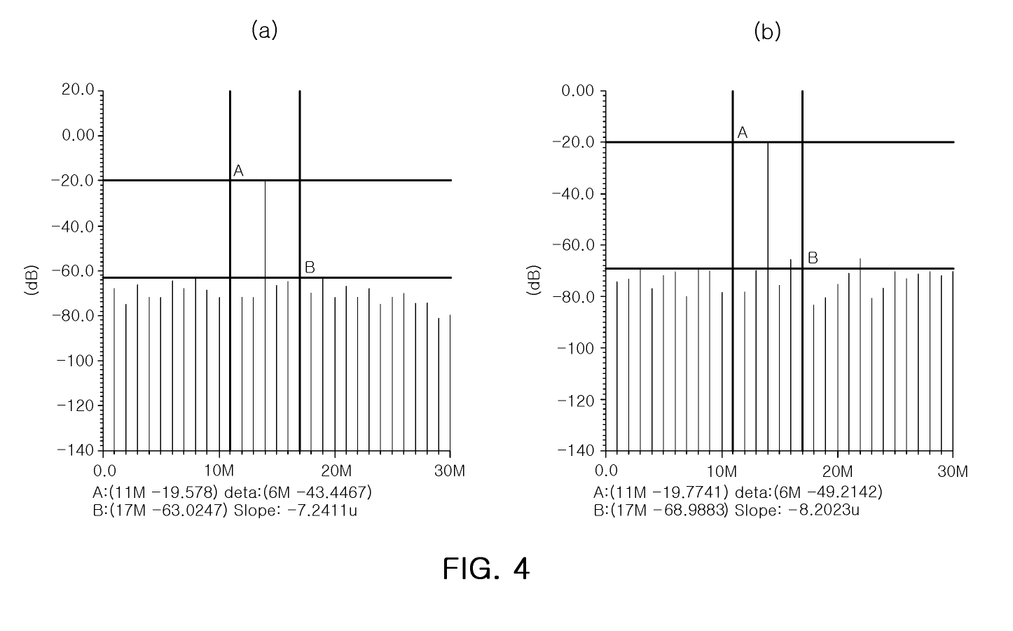

FIGS. 4(a) and 4(b) are graphs showing a desired signal and tertiary harmonics according to an exemplary embodiment of the present invention. Specifically, FIG. 4(a) is a graph showing the difference between the desired signal and tertiary harmonics when the first and second injection/extraction circuit units 410 and 420 are omitted, and FIG. 4(b) is a graph showing the difference between a desired signal and tertiary harmonics when the first and second injection/extraction circuit units 410 and 420 are provided.

In FIGS. 4(a) and 4(b), point A indicates the peak of the desired signal, point B indicates the peak of the tertiary harmonics, delta indicates the difference between points A and B, and slope indicates a tilt of the signal waveforms.

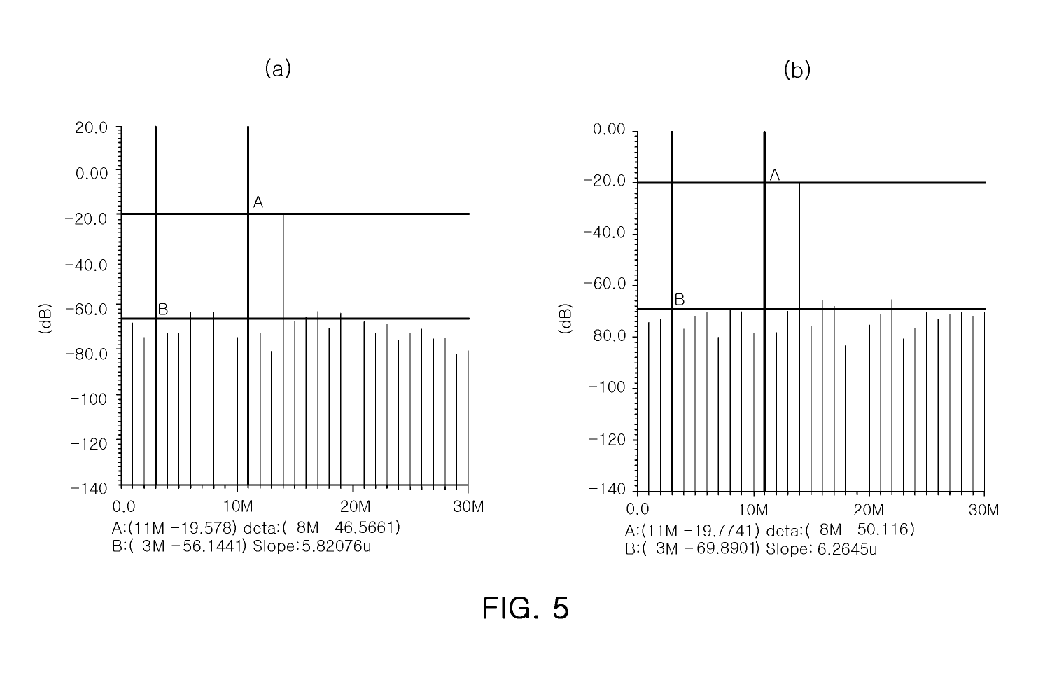

FIGS. 5(a) and 5(b) are graphs showing a desired signal and secondary harmonics according to an exemplary embodiment of the present invention. Specifically, FIG. 5(a) is a graph showing the difference between a desired signal and secondary harmonics when the first and second injection/extraction circuit units 410 and 420 are omitted, and FIG. 5(b) is a graph showing the difference between the desired signal and secondary harmonics when the first and second injection/extraction circuit units 410 and 420 are provided.

In FIGS. 5(a) and 5(b), point A indicates the peak of the desired signal, point B indicates the peak of the secondary harmonics, delta indicates the difference between points A and B, and slope indicates a tilt of the signal waveforms.

The operation and effect of the present invention will now be described with reference to the accompanying drawings.

The mixer with a differential DC offset cancellation function according to an exemplary embodiment of the present invention will now be described with reference to FIGS. 1 to 5. As shown in FIG. 1, the mixer with a differential DC offset cancellation function according to an exemplary embodiment of the present invention may include the load unit 100, the mixing unit 200, the first output voltage detection unit 310, the second output voltage detection unit 320, the first injection/extraction circuit unit 410, the second injection/extraction circuit unit 420, and the current regulation unit 500.

In the load unit 100, the first load unit 110 connected between the power source voltage terminal Vdd and the first output terminal OUT+provides a pre-set load resistance, and the second load unit 120 connected between the power source voltage terminal Vdd and the second output terminal OUT− provides a pre-set load resistance. Accordingly, a proper level of current required for operating the mixing unit 200 can be provided by the load resistance of the load unit 100 and the power source voltage Vdd.

The mixing unit 200, biased by the current from the load unit 110, mixes the input signals IN+ and IN− and the oscillation signals LO+ and LO−, and outputs the mixed signal through the first and second output terminals OUT+ and OUT−.

In more detail, for example, the mixing unit 200 may have a Gilbert cell structure with which the mixing unit 200 is connected between the load unit 100 and a ground.

The mixing unit 200 may include the gain stage 210 and the switching stage 220, and the first and second MOS transistors M21 and M22 of the gain stage 210 amplify an input signal and transfer the amplified signal to the switching stage 220.

The third and fourth transistors M23 and M24 of the switching stage 220 switch the input signal transferred from the first MOS transistor M21 of the gain stage unit 210 according to first and second oscillation signals. The fifth and sixth MOS transistors M25 and M26 of the switching stage 220 switch the input signal transferred from the second MOS transistor M22 of the gain stage 210 according to the first and second oscillation signals.

Through such switching operations, the switching stage 220 mixes the input signals and the oscillation signals and outputs the mixed signal through the output terminals OUT+ and OUT−.

While such operations are being performed, the load current can be properly regulated through the process of injecting or extracting current flowing across the load unit 100 according to the voltage size of the first and second output terminals OUT+ and OUT−, to thereby cancel a differential DC offset.

With reference to FIG. 1, the first output voltage detection unit 310 detects an output voltage of the first output terminal OUT+ to output the first detection voltage Vd1 to the first injection/extraction circuit unit 410. The second output voltage detection unit 320 detects an output voltage of the second output terminal OUT− to output the second detection voltage Vd2 to the second injection/extraction circuit unit 420.

The first injection/extraction circuit unit 410 extracts current to the first load unit 110 or extracts current from the first load unit 110 according to the size of the first detection voltage Vd1 from the first output voltage detection unit 310.

Also, the second injection/extraction circuit unit 420 extracts current to the second load unit 120 or extracts current from the second load unit 120 according to the size of the second detection voltage Vd2 from the second output voltage detection unit 320.

The current regulation unit 500 regulates the overall current flowing across the first injection/extraction circuit unit 410 and the second injection/extraction circuit unit 420.

In more detail, as shown in FIG. 1, the first load unit 110 may include first and second resistors R11 and R12 connected in series between the power source voltage terminal Vdd and the first output terminal OUT+, and the second load unit 120 may include third and fourth resistors R11 and R12 connected in series between the power source voltage terminal Vdd and the second output terminal OUT−.

The first output voltage detection unit 310, a detection node, may be connected to a first connection node N1 between the first and second resistors R11 and R12 or may be connected to the first output terminal OUT+. Likewise, the second output voltage detection unit 320, a detection node, may be connected to a second connection node N2 between the third and fourth resistors R21 and R22 or may be connected to the second output terminal OUT−. This will now be described with reference to FIG. 2.

For example, with reference to FIG. 2(a), when the first output voltage detection unit 310 (or the second output voltage detection unit 320) is connected to the first connection node N1 (or to the second connection node N2), the first output voltage detection unit 310 may include the resistor R33 and the capacitor C33. In this case, the first output voltage detection unit 310 may have an input terminal connected to the first connection node N1 between the first and second resistors R11 and R12 of the first load unit 110, and the second output voltage detection unit 320 may have an input terminal connected to the second connection node N2 between the third and fourth resistors R21 and R22 of the second load unit 120.

In contrast, with reference to FIG. 2(b), when the first output voltage detection unit 310 (or the second output voltage detection unit 320) is connected to the first output terminal OUT+(or the second output terminal OUT−), the first output voltage detection unit 310 (or the second output voltage detection unit 320) may include the first and second distribution resistors R31 and R32, the resistor R33 for outputting the voltage distributed by the first and second distribution resistors R31 and R32, and the capacitor C33.

With reference to FIG. 1, in the first injection/extraction circuit unit 410, the first and second transistors M41 and M42, which are different types of PMOS and NOMS transistors, respectively, complementarily operate according to the size of the single first detection voltage Vd1 transferred from the first output voltage detection unit 310.

Namely, in the first injection/extraction circuit unit 410, when the first transistor M41 is turned on and the second transistor M42 is turned off, current is injected into the first load unit 110 through the first transistor M41, and when the first transistor M41 is turned off and the second transistor M42 is turned on, current is extracted from the first load unit 110 through the second transistor M42.

In the second injection/extraction circuit unit 420, the third and fourth transistors M43 and M44, which are different types of PMOS and NOMS transistors, respectively, operate complementarily according to the size of the single second detection voltage Vd2 transferred from the second output voltage detection unit 320.

Namely, in the second injection/extraction circuit unit 420, when the third transistor M43 is turned on and the fourth transistor M44 is turned off, current is injected into the second load unit 120 through the third transistor M43, and when the third transistor M43 is turned off and the fourth transistor M44 is turned on, current is extracted from the second load unit 120 through the fourth transistor M44.

Accordingly, the first transistor M41 of the first injection/extraction circuit unit 410 operates complementarily with the third transistor M43 of the second injection/extraction circuit unit 420, and the second transistor M42 of the first injection/extraction circuit unit 410 operates complementarily with the fourth transistor M44 of the second injection/extraction circuit unit 420.

With reference to FIG. 3, in the first injection/extraction circuit unit 410, when the first transistor M41 is turned on, the second transistor M42 is turned off, so the current Iin flowing through the first transistor M41 is injected into the load unit 110.

Meanwhile, when the first transistor M41 is turned off and the second transistor M42 is turned on, a portion Iex of the current flowing across the load unit 110 through the second transistor M42 is extracted. According to this operation, the compensation voltage Vcmp compensated for by the first injection/extraction circuit unit 410 is determined by Equation 2 shown below:

Vcmp=(Iin−Iex)*RL/2 [Equation 2]

The second injection/extraction circuit unit 420 operates in the same manner as the first injection/extraction circuit unit 410 as described above.

As shown in the graph of FIG. 4(a), when the first and second injection/extraction circuit units 410 and 420 according to the exemplary embodiment of the present invention are omitted, the difference between the desired signal and the tertiary harmonics is about −43.4467.

In comparison, as shown in the graph of FIG. 4(b), when the first and second injection/extraction circuit units 410 and 420 according to the exemplary embodiment of the present invention are provided, the difference between the desired signal and the tertiary harmonics is about −49.2142.

Namely, with reference to FIGS. 4(a) and 4(b), it is noted that with the presence of the first and second injection/extraction circuit units 410 and 420, the difference between the desired signal and the tertiary harmonics is even larger.

As shown in the graph of FIG. 5(a), when the first and second injection/extraction circuit units 410 and 420 according to the exemplary embodiment of the present invention are omitted, the difference between the desired signal and the secondary harmonics is about −46.5661.

In comparison, as shown in the graph of FIG. 5(b), when the first and second injection/extraction circuit units 410 and 420 according to the exemplary embodiment of the present invention are provided, the difference between the desired signal and the secondary harmonics is about −50.116.

Namely, with reference to FIGS. 5(a) and 5(b), it is noted that with the presence of the first and second injection/extraction circuit units 410 and 420, the difference between the desired signal and the tertiary harmonics is even larger.

With reference to FIGS. 4 and 5, according to the exemplary embodiment of the present invention, the IM3 characteristics are better by 6 dB, and the IM2 characteristics are better by 4 dB. Current injection and current extraction are simultaneously applied to each load, so linearity can be improved when compared with the existing structure. Also, because each load is compensated for by lowering the compensation current to half, when compared with the existing structure, the mismatch compensation area can be further extended.

As described above, the basic operational principle of the present invention is using both the current injection and current extraction. Namely, mismatch according to output voltages is detected, and current is injected into one side and current is extracted from the other side by the difference therebetween.

In this case, the first and third transistors are responsible for current injection, and the second and fourth transistors are responsible for current extraction.

The overall load resistance of each of the first and second load units 110 and 120 of the load unit 100 is RL, respectively, but in order to minimize the influence of the compensation circuit in the overall operation, the compensation circuit may operate at the intermediate part RL/2.

The first to fourth transistors M41 to M44 operate in a linear area and are large by more than 10 times compared with the RL resistance value (hundreds of Ω to a few Ω), so their influence on the load resistance value is extremely small (insignificant).

As set forth above, according to exemplary embodiments of the invention, a differential DC offset can be compensated for by injecting and extracting a load current according to an output voltage, and thus, linearity can be improved.

While the present invention has been shown and described in connection with the exemplary embodiments, it will be apparent to those skilled in the art that modifications and variations can be made without departing from the spirit and scope of the invention as defined by the appended claims.

What is claimed is:

1. A mixer with a differential DC offset cancellation function, the mixer comprising:
a load unit including a first load unit connected between a power source voltage terminal and a first output terminal and a second load unit connected between the power source voltage terminal and a second output terminal;
a mixing unit biased by current transferred from the load unit to mix input signals and oscillation signals and outputting the mixed signal generated through the mixing operation through the first and second output terminals;
a first output voltage detection unit detecting an output voltage of the first output terminal;
a second output voltage detection unit detecting an output voltage of the second output terminal;
a first injection/extraction circuit unit injecting current into the first load unit or extracting current from the first load unit according to the size of a first detection voltage detected by the first output voltage detection unit;
a second injection/extraction circuit unit injecting current into the second load unit or extracting current from the second load unit according to the size of a second detection voltage detected by the second output voltage detection unit; and
a current regulation unit regulating an overall current flowing across the first and second injection/extraction circuit units.

2. The mixer of claim 1, wherein the first load unit comprises:
first and second resistors connected in series between the power source voltage terminal and the first output terminal, and
the second load unit comprises third and fourth resistors connected in series between the power source voltage terminal and the second output terminal.

3. The mixer of claim 2, wherein the first output voltage detection comprises an input terminal connected to a first connection node between the first and second resistors of the first load unit, and
the second output voltage detection unit comprises an input terminal connected to a second connection node between the third and fourth resistors of the second load unit.

4. The mixer of claim 3, wherein the first injection/extraction circuit unit comprises:
a first PMOS transistor having a source connected with the power source voltage terminal, a gate connected with an output terminal of the first output voltage detection unit, and a drain connected to the first connection node between the first and second resistors of the first load unit; and
a second NMOS transistor having a drain connected to the first connection node between the first and second resistors of the first load unit, a gate connected to the output terminal of the first output voltage detection unit, and a source connected to the current regulation unit.

5. The mixer of claim 4, wherein the second injection/extraction circuit unit comprises:
a third PMOS transistor having a source connected to the power source voltage terminal, a gate connected to an output terminal of the second output voltage detection unit, and a drain connected to the second connection node between the third and fourth resistors of the second load unit; and
a fourth NMOS transistor having a drain connected to the second connection node between the third and fourth resistors of the second load unit, a gate connected to the output terminal of the second output voltage detection unit, and a source connected to the current regulation unit.

6. The mixer of claim 5, wherein the current regulation unit comprises:
a fifth NMOS transistor having a drain connected to a connection node between the source of the second MOS transistor and the source of the fourth transistor, a gate connected to a bias voltage, and a source connected to a ground.

7. The mixer of claim 5, wherein, in the first injection/extraction circuit unit, the first and second transistors operate complementarily according to the size of the first detection voltage from the first output voltage detection unit.

8. The mixer of claim 7, wherein when the first transistor is turned on, the first injection/extraction circuit unit injects current to the first load unit through the first transistor, and when the second transistor is turned on, the first injection/extraction circuit unit extracts current from the first load unit through the second transistor.

9. The mixer of claim 8, wherein, in the second injection/extraction circuit unit, the third and fourth transistors operate complementarily according to the size of the second detection voltage from the second output voltage detection unit.

10. The mixer of claim 9, wherein when the third transistor is turned on, the second injection/extraction circuit unit injects current to the second load unit through the third transistor, and when the fourth transistor is turned on, the second injection/extraction circuit unit extracts current from the second load unit through the fourth transistor.

11. The mixer of claim 10, wherein the first transistor of the first injection/extraction circuit unit complementarily operates with the third transistor of the second injection/extraction circuit unit.

12. The mixer of claim 11, wherein the second transistor of the first injection/extraction circuit unit complementarily operates with the fourth transistor of the second injection/extraction circuit unit.

13. A mixer with a differential DC offset cancellation function, the mixer comprising:
a load unit including a first load unit connected between a power source voltage terminal and a first output terminal and a second load unit connected between the power source voltage terminal and a second output terminal;
a mixing unit having a Gilbert cell structure connected between the load unit and a ground, mixing input signals and oscillation signals, and outputting the mixed signal through the first and second output terminals;
a first output voltage detection unit detecting an output voltage of the first output terminal;
a second output voltage detection unit detecting an output voltage of the second output terminal;
a first injection/extraction circuit unit injecting current into the first load unit or extracting current from the first load unit according to the size of a first detection voltage detected by the first output voltage detection unit;
a second injection/extraction circuit unit injecting current into the second load unit or extracting current from the second load unit according to the size of a second detection voltage detected by the second output voltage detection unit; and
a current regulation unit regulating an overall current flowing across the first and second injection/extraction circuit units.

14. The mixer of claim 13, wherein the mixing unit comprises:
a gain stage including first and second MOS transistors receiving an input signal; and
a switching stage including third and fourth MOS transistors switching an input signal transferred from the first MOS transistor of the gain stage according to an oscillation signal and fifth and sixth transistors switching an input signal transferred from the second MOS transistor of the gain stage according to an oscillation signal.

15. The mixer of claim 14, wherein the first load unit comprises:
first and second resistors connected in series between the power source voltage terminal and the first output terminal, and
the second load unit comprises third and fourth resistors connected in series between the power source voltage terminal and the second output terminal.

16. The mixer of claim 15, wherein the first output voltage detection comprises an input terminal connected to a first connection node between the first and second resistors of the first load unit, and
the second output voltage detection unit comprises an input terminal connected to a second connection node between the third and fourth resistors of the second load unit.

17. The mixer of claim 16, wherein the first injection/extraction circuit unit comprises:
a first PMOS transistor having a source connected with the power source voltage terminal, a gate connected with an output terminal of the first output voltage detection unit, and a drain connected to the first connection node between the first and second resistors of the first load unit; and
a second NMOS transistor having a drain connected to the first connection node between the first and second resistors of the first load unit, a gate connected to the output terminal of the first output voltage detection unit, and a source connected to the current regulation unit.

18. The mixer of claim 17, wherein the second injection/extraction circuit unit comprises:
a third PMOS transistor having a source connected to the power source voltage terminal, a gate connected to an output terminal of the second output voltage detection unit, and a drain connected to the second connection node between the third and fourth resistors of the second load unit; and
a fourth NMOS transistor having a drain connected to the second connection node between the third and fourth resistors of the second load unit, a gate connected to the output terminal of the second output voltage detection unit, and a source connected to the current regulation unit.

19. The mixer of claim 18, wherein the current regulation unit comprises:
a fifth NMOS transistor having a drain connected to a connection node between the source of the second MOS transistor and the source of the fourth transistor, a gate connected to a bias voltage, and a source connected to a ground.

20. The mixer of claim 18, wherein, in the first injection/extraction circuit unit, the first and second transistors operate complementarily according to the size of the first detection voltage from the first output voltage detection unit.

21. The mixer of claim 20, wherein when the first transistor is turned on, the first injection/extraction circuit unit injects current to the first load unit through the first transistor, and when the second transistor is turned on, the first injection/extraction circuit unit extracts current from the first load unit through the second transistor.

22. The mixer of claim 21, wherein, in the second injection/extraction circuit unit, the third and fourth transistors operate complementarily according to the size of the second detection voltage from the second output voltage detection unit.

23. The mixer of claim 22, wherein when the third transistor is turned on, the second injection/extraction circuit unit injects current to the second load unit through the third transistor, and when the fourth transistor is turned on, the second injection/extraction circuit unit extracts current from the second load unit through the fourth transistor.

24. The mixer of claim 23, wherein the first transistor of the first injection/extraction circuit unit complementarily operates with the third transistor of the second injection/extraction circuit unit.

25. The mixer of claim 13, wherein the second transistor of the first injection/extraction circuit unit complementarily operates with the fourth transistor of the second injection/extraction circuit unit.
